(19) United States
(12) Patent Application Publication
(10) Pub. No.: US 2026/0136964 A1
(43) Pub. Date: May 14, 2026

(54) PACKAGE SUBSTRATE INCLUDING INDUCTOR

(71) Applicant: Samsung Electronics Co., Ltd., Suwon-si (KR)

(72) Inventors: Juwon Kim, Suwon-si (KR); Seokbeom Yong, Suwon-si (KR); Seulgi Yu, Suwon-si (KR)

(21) Appl. No.: 19/351,372

(22) Filed: Oct. 7, 2025

(30) Foreign Application Priority Data
Nov. 8, 2024 (KR) 10-2024-0158174

(51) Int. Cl. H01L 23/498

(52) U.S. Cl. CPC H10W 70/635; H10W 70/65; H10W 70/69; H10W 90/701

(57) ABSTRACT

A semiconductor package includes a core stack structure including a core substrate, and core insulating layers stacked on a lower portion of the core substrate; and a signal structure penetrating through the core substrate and the core insulating layers. The signal structure includes an external connection pad on the lower surface of the lowermost core insulating layer and a signal pad on the lower surface of the lowermost core insulating layer or between the core insulating layers; a ground structure penetrating through the core substrate and the core insulating layers. The ground structure includes a lower ground pad on the lower surface of the lowermost core insulating layer, and a middle ground pad between the core insulating layers and extending onto the external connection pad; and an inductor mounted between the external connection pad and the signal pad.

### CROSS-REFERENCE TO RELATED APPLICATION(S)

This application claims benefit of priority to Korean Patent Application No. 10-2024-0158174 filed on Nov. 8, 2024, in the Korean Intellectual Property Office, the disclosure of which is incorporated herein by reference in its entirety.

### BACKGROUND

The present disclosure relates to a package substrate, and a semiconductor package using the package substrate.

As semiconductor chips become faster and more densely integrated, semiconductor packages are also having a significant impact on satisfying the characteristics of the entire semiconductor product. Specifically, when high-performance semiconductor chips are packaged, it is generally required that signals be transmitted without distortion in high-speed digital and high-frequency analog circuits to ensure accurate operation and reliability of a system. Accordingly, with an increase in the size of semiconductor packages, it is important that transmitted high-speed digital signals be transmitted without distortion caused by obstacles to a point at which the digital signals are transmitted. For example, it is desirable for high-speed digital signals to reach their destination without distortion caused by any interference or attenuation.

### SUMMARY

An aspect of the present disclosure is to provide a package substrate having improved high-speed digital signal transmission characteristics.

As a means of addressing the aforementioned and other aspects, in an example embodiment of the present disclosure, provided is a semiconductor package, including: a core substrate having a first surface and a second surface facing away from each other; a plurality of core insulating layers stacked on the first surface of the core substrate, the plurality of core insulating layers including a lowermost core insulating layer; a signal connection path formed through the core substrate and the plurality of core insulating layers, the signal connection path configured to be directly electrically connected to a signal voltage; a ground connection path formed through the core substrate and the plurality of core insulating layers, the ground connection path configured to be directly electrically connected to a ground voltage; a semiconductor chip formed on the second surface of the core substrate and electrically connected to the signal connection path and to the ground connection path; and an inductor. The signal connection path includes: an external connection pad disposed on a lower surface of the lowermost core insulating layer, and a signal pad disposed on the lower surface of the lowermost core insulating layer or between the plurality of core insulating layers. The external connection pad is spaced apart from the signal pad in a horizontal direction. The ground connection path includes: a lower ground pad disposed on the lower surface of the lowermost core insulating layer, and a middle ground pad disposed between the plurality of core insulating layers and extending onto the external connection pad. The inductor is mounted between the external connection pad and the signal pad and electrically connect the external connection pad and the signal pad to each other.

In an example embodiment of the present disclosure, provided is a semiconductor package including: a substrate having a first surface and a second surface facing away from each other; a plurality of core insulating layers stacked on the first surface of the substrate, the plurality of core insulating layers including a lowermost core insulating layer; a semiconductor chip formed on the second surface of the substrate; a lower ground pad disposed on a lower surface of the lowermost core insulating layer, the lower ground pad configured to be directly electrically connected to a ground voltage; an external connection pad spaced apart from the lower ground pad and disposed on the lower surface of the lowermost core insulating layer; a signal pad spaced apart from the lower ground pad and the external connection pad and disposed on the lower surface of the lowermost core insulating layer, the signal pad configured to be directly electrically connected to a signal voltage; ; an external connection pad spaced apart from the lower ground pad and disposed on the lower surface of the lowermost core insulating layer; a signal pad spaced apart from the lower ground pad and the external connection pad and disposed on the lower surface of the lowermost core insulating layer, the signal pad configured to be directly electrically connected to a signal voltage; a solder resist layer disposed below the plurality of core insulating layers, wherein the solder resist layer covers the lower ground pad, the external connection pad, and the signal pad, and includes a first opening exposing a first surface of the external connection pad, a second opening exposing a second surface of the external connection pad, and a third opening exposing the signal pad; an inductor disposed on a lower surface of the solder resist layer; a connection bump disposed in the first opening and electrically connected to the external connection pad; and first conductive connectors disposed in the second opening and the third opening and electrically connecting the inductor to the external connection pad and the signal pad.

In an example embodiment, provided is a semiconductor package including: a core substrate having a first surface and a second surface facing away from each other; a plurality of core insulating layers stacked on the first surface of the core substrate; a signal connection path formed through the core substrate and the plurality of core insulating layers and extending to the first surface of the core substrate, the signal connection path configured to be directly electrically connected to a signal voltage; and a semiconductor chip formed on the second surface of the core substrate and electrically connected to the signal connection path. The signal connection path includes: a signal core via penetrating through the core substrate, a plurality of vias each of which penetrates through a corresponding one of the plurality of core insulating layers, the plurality of vias arranged below the signal core via and electrically connected to the signal core via, a signal pad contacting a lowermost one of the plurality of vias, and extending horizontally along a lower surface of the plurality of core insulating layers, an external connection pad spaced apart from the signal pad in a horizontal direction and disposed on the lower surface of the plurality of core insulating layers, and an inductor disposed between the external connection pad and the signal pad. The signal pad includes a first end and a second end opposite the first end, and the first end does not overlap the signal core via in a plan view. The first end of the signal pad is spaced apart from the signal core via in the horizontal direction. The external connection pad includes a first end and a second end opposite the first end. The first end of the external connection pad is adjacent to the first end of the signal pad. The inductor is connected to the first end and the second end.

According to an embodiment of the invention, a semiconductor package includes: a plurality of core insulating layers having a first surface and a second surface facing away from the first surface; a signal connection path formed through the plurality of core insulating layers and extending from the first surface to the second surface, the signal connection path is configured to be directly electrically connected to a signal voltage; and a semiconductor chip formed on the second surface of the plurality of core insulating layers and electrically connected to the signal connection path. The signal connection path includes: a plurality of vias each of which penetrates through a corresponding one of the plurality of core insulating layers, a first interconnection pattern contacting a lowermost one of the plurality of vias, and extending horizontally along a lower surface of the plurality of core insulating layers, a second interconnection pattern spaced apart from the first interconnection pattern in a horizontal direction and disposed on the lower surface of the plurality of core insulating layers, a connection bump electrically connected to and in contact with the second interconnection pattern, and an inductor disposed between the first and second interconnection patterns. The first and second interconnection patterns are electrically connected to each other through the plurality of vias. The first interconnection pattern includes a first end and a second end opposite the first end. The second interconnection pattern includes a first end and a second end opposite the first end. The second end of the second interconnection pattern is adjacent to the first end of the first interconnection pattern. The inductor is connected to the first end of the first interconnection pattern and the second end of the second interconnection pattern.

According to example embodiments of the present disclosure, an inductor may be disposed between an external connection pad and a signal pad, thereby providing a package substrate having improved high-speed signal transmission characteristics and improved reliability.

Advantages and effects of the present disclosure are not limited to the foregoing content and may be more easily understood in the process of describing a specific example embodiment of the present disclosure.

### BRIEF DESCRIPTION OF DRAWINGS

The above and other aspects, features, and advantages of the present invention will be more clearly understood from the following detailed description, taken in conjunction with the accompanying drawings, in which:

FIG. 1 is a plan view illustrating a package substrate according to an example embodiment;

FIG. 2 is a bottom view illustrating a package substrate according to an example embodiment;

FIG. 3 is a cross-sectional view taken along line I-I′ of a package substrate of FIG. 1 according to an example embodiment;

FIG. 4A is an enlarged view of part ‘A’ of FIG. 3;

FIG. 4B is a partially enlarged view for explaining a package substrate according to a modified example embodiment;

FIG. 5 is a cross-sectional view taken along line I-I′ of a package substrate of FIG. 1 according to an example embodiment;

FIG. 6 is a cross-sectional view taken along line I-I′ of a package substrate of FIG. 1 according to an example embodiment;

FIG. 7A is a plan view illustrating a semiconductor package according to an example embodiment, and FIG. 7B is a cross-sectional view taken along line II-II′ of FIG. 7;

FIG. 8 is a cross-sectional view illustrating a semiconductor package according to an example embodiment;

FIGS. 9A to 9C are views illustrating a manufacturing process of a package substrate according to an example embodiment; and

FIG. 10 is a graph illustrating signal transmission characteristics according to an example embodiment of the present disclosure.

### DETAILED DESCRIPTION

Hereinafter, example embodiments of the present disclosure will be described with reference to the accompanying drawings. Unless otherwise specified, in the present specification, it may be understood that the expressions such as “on,” “above,” “upper,” “below,” “beneath,” “lower,” and “side,” are merely indicated based on drawings, and may actually vary depending on the direction in which the components are disposed.

In order to distinguish various elements, steps and directions from each other, ordinal numbers such as “first,” “second,” “third,” etc. may be used as labels of specific elements, steps, and directions to distinguish such elements, steps, etc. Terms not described using “first,” “second,” etc. in the specification may still be referred to as “first” or “second” in the claim. In addition, terms referred to as specific ordinal numbers (e.g., “first” in certain claims) may be described as different ordinal numbers (e.g., “second” in specifications or other claims) elsewhere.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

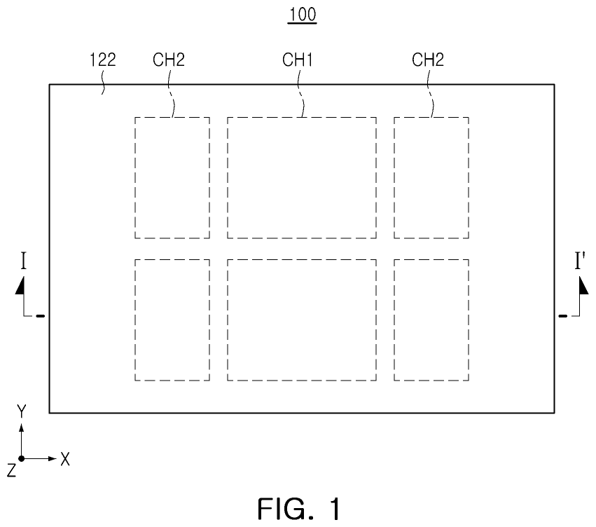

FIG. 1 is a plan view illustrating a package substrate 100 according to an example embodiment;

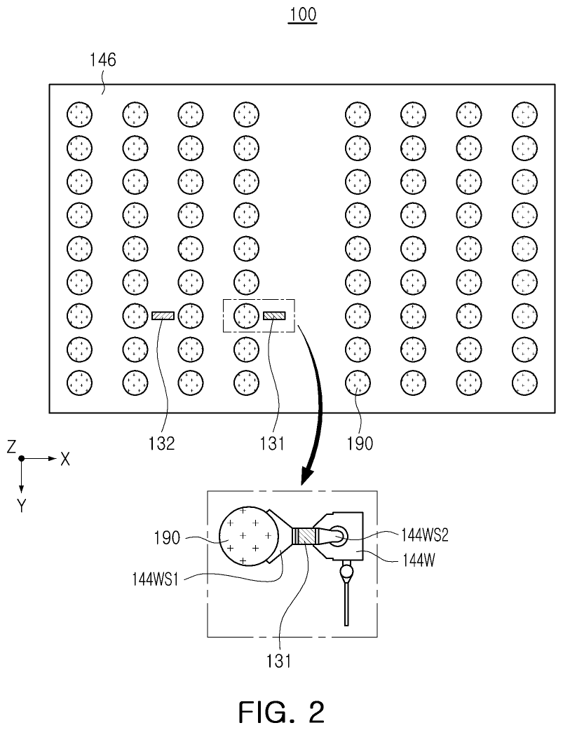

FIG. 2 is a bottom view illustrating a package substrate according to an example embodiment.

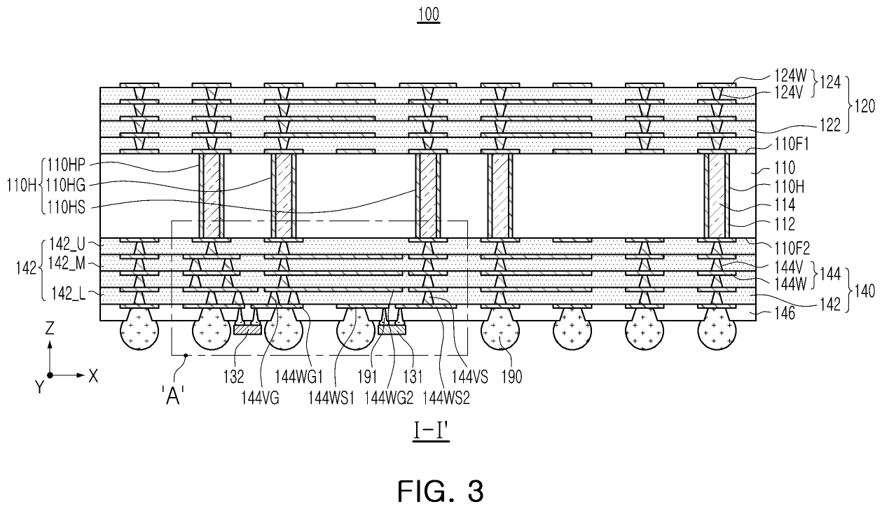

FIG. 3 is a cross-sectional view taken along line I-I′ of a package substrate of FIG. 1 according to an example embodiment.

Referring to FIGS. 1 to 3, the package substrate 100 may include a core substrate 110, a first core stacked structure 120 (e.g., a first core stack), and a second core stacked structure 140.

As illustrated in FIG. 1, the package substrate 100 may be configured such that a first semiconductor chip CH1 and a second semiconductor chip CH2 are mounted on a central portion of the package substrate 100 from a planar perspective. FIG. 1 is a plan view illustrating the configuration for mounting the first and second semiconductor chips CH1 and CH2 on the package substrate 100, thereby forming a semiconductor package, though the first and second chips CH1 and CH2 are not depicted in FIGS. 2 and 3.

The core substrate 110 may include a first surface 110F1 and a second surface 110F2, opposite to the first surface 110F1. A core via 110H may be disposed to penetrate through the core substrate 110 from the first surface 110F1 to the second surface 110F 2 of the core substrate 110, and a conductive layer 112 and a conductive via 114 may be disposed within the core via 110H. The conductive layer 112 and the conductive via 114 may provide an electrical path through the core via 110H.

The core via 110H may include a power core via 110HP, a ground core via 110HG, and a signal core via 110HS.

The power core via 110HP may be directly electrically connected to a power voltage during an operation of the semiconductor package (or a semiconductor chip therein). The power core via 110HP may penetrate through the core substrate 110 in a direction perpendicular to the first surface 110F1 and the second surface 110F2 of the core substrate 110 (e.g., in the Z-direction).

The ground core via 110HG may be directly electrically connected to a ground voltage during an operation of the semiconductor package. The ground core via 110HG may penetrate through the core substrate 110 in the direction perpendicular to the core substrate 110 (e.g., in the Z-direction).

The signal core via 110HS may be directly electrically connected to a signal voltage during an operation of the semiconductor package. The signal core via 110HS may penetrate through the core substrate 110 in the direction perpendicular to the core substrate 110 (e.g., in the Z-direction).

For example, the ground voltage (e.g., VSS) may serve as an electrical reference during the operation of the semiconductor chips CH1 and CH2, and may be connected to circuit elements. The power voltage (e.g., VDD) may supply the power for the operation of the semiconductor chips CH1 and CH2, and may be connected to circuit elements. Both the ground voltage and the power voltage may maintain a constant frequency and/or voltage magnitude, so that the circuit elements are configured to operate with a stable frequency or voltage. The signal voltage may include a command signal, a clock signal, or similar signals, and its frequency and/or signal magnitude may vary. In some embodiments, the signal voltage may be also used to exchange data with memory cells, enabling the storage or retrieval of data through circuit elements that facilitate data transmission and exchange.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors (such as, for example, wires, pads, internal electrical lines, through vias, etc.) and/or passive elements (such as, for example, a capacitor, an inductor, beads, etc.). As such, directly electrically connected components do not include components electrically connected through active elements, such as transistors or diodes.

In example embodiments, the core substrate 110 may be an insulating substrate. For example, the core substrate 110 may include an insulating material, for example, a thermosetting resin such as an epoxy resin, or a thermoplastic resin such as a polyimide. For example, the core substrate 110 may be formed of prepreg, ABF, or FR-4, which may include an inorganic filler or/and glass fiber.

The conductive layer 112 and the conductive via 114 may include at least one of copper (Cu), nickel (Ni), chromium (Cr), titanium (Ti), gold (Au), platinum (Pt), silver (Ag), or tungsten (W).

The first core stack structure 120 may be disposed on the first surface 110F1 of the core substrate 110. The first core stack structure 120 may include a plurality of first core insulating layers 122 and a plurality of first core interconnection layers 124. In example embodiments, the plurality of first core insulating layers 122 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof. The interlayer insulating layer may be formed using a chemical vapor deposition (CVD) process, a flowable-CVD process, or a spin coating process.

Each of the plurality of first core interconnection layers 124 may be disposed between a corresponding pair of the plurality of first core insulating layers 122, or may be covered by one of the plurality of first core insulating layers 122. The plurality of first core interconnection layers 124 may form upper conductive paths electrically connected to the core substrate 110, and may include a via portion (or via or a plurality of vias) 124V and an interconnection portion (or interconnection pattern or a plurality of interconnection patterns) 124W. The plurality of vias 124V and the plurality of interconnection patterns 124W may be parts of a plurality of electrical connection paths.

For example, though not shown in the drawing, the first and second semiconductor chips CH1 and CH2, which are to be formed on the package substrate 100, may be electrically connected to the upper conductive paths.

The interconnection portion 124W may extend in a horizontal direction (e.g., an X-direction or a Y-direction), and may be disposed on a plurality of vertical (e.g., a Z-direction) levels. For example, as described in FIG. 3, four sets of interconnection portions 124W may be arranged at different height levels from each other.

The via portion 124V may be disposed inside a via hole penetrating through the plurality of first core insulating layers 122 and may connect the interconnection portions 124W between the interconnection portions 124W disposed on different vertical (e.g., the Z-direction) levels.

In example embodiments, the via 124V and the interconnection portion 124W may include at least one of copper (Cu), nickel (Ni), chromium (Cr), titanium (Ti), gold (Au), platinum (Pt), silver (Ag), or tungsten (W). For example, the via 124V may be a conductive via.

The second core stacked structure 140 may be disposed below the second surface 110F2 of the core substrate 110. The second core stacked structure 140 may include a plurality of second core insulating layers 142 and a plurality of second core interconnection layers 144.

As illustrated in FIG. 3, the plurality of second core insulating layers 142 may include the uppermost core insulating layer 142_U, the lowermost core insulating layer 142_L, and at least one middle core insulating layer 142_M. The uppermost core insulating layer 142_U may refer to a layer disposed below the second surface 110F2 of the core substrate 110 and disposed in a position closest to the core substrate 110. The lowermost core insulating layer 142_L may refer to a layer disposed farthest from the second surface 110F2 of the core substrate 110. At least one middle core insulating layer 142_M may refer to a layer disposed between the uppermost core insulating layer 142_U and the lowermost core insulating layer 142_L.

In example embodiments, the plurality of second core insulating layers 142 may include FOX, TOSZ, USG, BSG, PSG, BPSG, PETEOS, FSG, HDP oxide, PEOX, FCVD oxide, or combinations thereof. The interlayer insulation layer may be formed using a chemical vapor deposition (CVD), a flowable-CVD process, or a spin coating process.

Each of the plurality of second core interconnection layers 144 may be disposed between a corresponding pair of the plurality of second core insulating layers 142, or may be covered with one of the plurality of second core insulating layers 142. The plurality of second core interconnection layers 144 may form a lower conductive path electrically connected to the core substrate 110, and may include an interconnection portion (or an interconnection pattern or a plurality of interconnection patterns) 144W and a via portion (or via or a plurality of vias) 144V. The plurality of vias 144V and the plurality of interconnection patterns 144W may be parts of a plurality of electrical connection paths.

The interconnection portion 144W may extend in a horizontal direction (e.g., in the X-direction or the Y-direction) between the plurality of second core insulating layers 142, and may be disposed on a plurality of vertical (e.g., in the Z-direction) levels.

For example, the interconnection portion 144W may include various wirings (or interconnection lines) and various pads. The pads may generally have a planar upper surface having horizontal dimensions (e.g., in both the X and Y directions) to facilitate connections thereto (e.g., to provide a larger surface to contact a later formed via). From a top down view, a pad may have a symmetrical shape (e.g., an oval (e.g., circle or ring) or a polygonal shape (e.g., square or rectangle) footprint). The pads may have a planar surface having dimensions greater than wiring (e.g., X-Y horizontal dimensions of a pad are both greater than the width of an internal wiring to which it is connected) to promote an electrical connection to a further terminal, such as a bump or solder ball, and/or an external wiring. For example, a horizontal wiring may be integrally formed with a pad (e.g., patterned out of the same metal layer) such that the wiring and pad have coplanar upper surfaces, with both of the X and Y horizontal dimensions of the pad being greater than the horizontal width of the wiring (e.g., greater or equal to 3 times the horizontal width of the wiring). In other examples, a pad may be discretely formed such that it is not in contact with any wiring formed at its vertical level within the device and is only connected to wiring within the device by vias. From a top down view, a pad may have X and Y horizontal dimensions that are about the same (e.g., within half to two times of the other), However, the invention is not limited thereto. For example, the X and Y horizontal dimensions may be different from each other.

The interconnection portion 144W may include a lower ground pad 144WG1 and a middle ground pad 144WG2, which are interconnection patterns 144W directly electrically connected to a ground voltage. Additionally, the interconnection portion 144W may include an external connection pad 144WS1 and a signal pad 144WS2, which are interconnection portions 144W directly electrically connected to the signal voltage.

In an example embodiment, the lower ground pad 144WG1 may be referred to as an interconnection portion 144W directly electrically connected to the ground voltage and disposed on the lower surface of the lowermost core insulating layer 142_L. A grounding system (or ground voltage) may be provided to the interconnection portion 144W disposed in the lowermost portion to prevent damage to the device, noise during device operation, or malfunction of the device.

The middle ground pad 144WG2 may be referred to as one of the interconnection portions 144W directly electrically connected to the ground voltage and disposed between the lowermost core insulating layer 142_L and the uppermost core insulating layer 142_U. In an example embodiment, the number of middle ground pads 144WG2 may be two or more and the middle ground pads 144WG2 may be disposed on a plurality of vertical levels. In this case, parasitic capacitance may occur between the plurality of middle ground pads 144WG2 and the external connection pad 144WS1.

In an example embodiment, the middle ground pad 144WG2 may be referred to as an interconnection portion 144W directly electrically connected to the ground voltage and disposed on an upper surface of the lowermost core insulating layer 142_L. The middle ground pad 144WG2 and the external connection pad 144WS1 may be spaced apart from each other with (or by) the lowermost core insulating layer 142 interposed therebetween. The middle ground pad 144WG2 may extend from above the lower ground pad 144WG1 along the core insulating layer 142 to above the external connection pad 144WS1. In this case, the middle ground pad 144WG2 and the external connection pad 144WS1 may overlap each other in a direction perpendicular to a lower surface of the external connection pad 144WS1, and this overlap may cause parasitic capacitance to occur as the core insulating layer 142 acts as a dielectric between the middle ground pad 144WG2 and the external connection pad 144WS1.

In an example embodiment, the external connection pad 144WS1 may be referred to as one of the interconnection portions 144W directly electrically connected to the signal voltage and disposed on the lower surface of the lowermost core insulating layer 142_L. The external connection pad 144WS1 may be disposed on the lower surface of the lowermost core insulating layer 142_L spaced apart from the ground pads 144WG1 and 144WG2. The external connection pad 144WS1 may overlap a region, in which the middle ground pad 144WG2 is disposed, in a direction perpendicular to the lower surface of the lowermost core insulating layer 142_L (e.g., in the Z-direction).

In an example embodiment, the external connection pad 144WS1 may be disposed below a region in which the middle ground pad 144WG2 is disposed, and an area of a region occupied by the external connection pad 144WS1 may be smaller than an area of a region in which the middle ground pad 144WG2 is disposed. For example, in a plan view (as viewed from the Z-direction), the area in a horizontal plane occupied by the external connection pad 144WS1 may be smaller than the area in the horizontal plane occupied by the middle ground pad 144WG2. Accordingly, the external connection pad 144WS1 may completely overlap a region, in which the middle ground pad 144WG2 is disposed, in the direction perpendicular to the core substrate 110 (e.g., the Z-direction).

Accordingly, a parasitic capacitance may occur between the middle ground pad 144WG2 and the external connection pad 144WS1. The parasitic capacitance may deteriorate the signal integrity. A magnitude of the parasitic capacitance may vary depending on an area of a region in which the middle ground pad 144WG2 and the external connection pad 144WS1 overlap each other. The magnitude of the parasitic capacitance may vary depending on the distance between the middle ground pad 144WG2 and the external connection pad 144WS1. For example, when the area of the region, in which the middle ground pad 144WG2 and the external connection pad 144WS1 overlap each other, increases, the magnitude of the parasitic capacitance may increase. For example, when the distance between the middle ground pad 144WG2 and the external connection pad 144WS1 becomes closer, the magnitude of the parasitic capacitance may increase. Accordingly, the signal integrity may deteriorate.

The signal pad 144WS2 may be referred to as an interconnection portion 144W disposed on the lower surface of a signal via portion 144VS. The signal via portion (or signal via) 144VS may be one of a set of vias disposed on a lowermost level among the via portions 144V disposed on the plurality of vertical (e.g., the Z-direction) levels. The signal via 144VS may be electrically connected to the signal core via 110HS. In an example embodiment, the signal pad 144WS2 may be spaced apart from the ground pads 144WG1 and 144WG2 and the external connection pad 144WS1. The signal pad 144WS2 may thus be disposed on the lower surface of the lowermost core insulating layer 142_L. In this case, the lower surface of the external connection pad 144WS1 and a lower surface of the signal pad 144WS2 may be coplanar with each other.

A parasitic capacitance may occur between the plurality of interconnection portions 144W and the signal pad 144WS2. The signal integrity may be deteriorated due to the parasitic capacitance. The magnitude of the parasitic capacitance may vary depending on a planar area of a region in which the plurality of interconnection portions 144W and the signal pad 144WS2 overlap each other. For example, when the planar area of the region in which the plurality of interconnection portions 144W and the signal pad 144WS2 overlap each other increases, the magnitude of the parasitic capacitance may increase.

A configuration bottom view of FIG. 2 illustrates a positional relationship by expressing only a connection bump 190, the external connection pad 144WS1, an inductor 131, the signal pad 144WS2, and the plurality of interconnection portions 144W. Referring to the configuration bottom view of FIG. 2, an area of the signal pad 144WS2 may be made smaller than that of the external connection pad 144WS1 to minimize the deterioration of signal integrity due to the parasitic capacitance occurring between the signal pad 144WS2 and the plurality of interconnection portions 144W. For example, in a plan view, the area in a horizontal plane occupied by the signal pad 144WS2 may be smaller than the area in the horizontal plane occupied by the external connection pad 144WS1.

The via portion (or via) 144V may be disposed inside a via hole penetrating through the plurality of second core insulating layers 142, and may connect the interconnection portions 144W between the interconnection portions 144W disposed on different vertical (e.g., the Z-direction) levels. The via portion 144V may include a ground via portion (or ground via) 144VG and a signal via portion (or signal via) 144VS.

The ground via portion 144VG may connect the lower ground pad 144WG1 and the middle ground pad 144WG2 such that the lower ground pad 144WG1 is directly electrically connected to the ground voltage. In an example embodiment, the ground via portion 144VG may refer to a via portion 144V disposed between the middle ground pad 144WG2 disposed on an upper surface of the lowermost core insulating layer 142_L and the lower ground pad 144WG1.

One or more ground via portions 144VG may be provided. A plurality of ground via portions 144VG may be disposed between the lower ground pad 144WG1 and the middle ground pad 144WG2 to minimize electromagnetic interference.

The signal via portion 144VS may be referred to as the lowermost via portion 144VS, among the via portions 144V disposed on the plurality of vertical (e.g., the Z-direction) levels electrically connected to the signal core via 110HS. The signal via portion 144VS may connect the interconnection pattern 144W directly electrically connected to the signal voltage and the signal pad 144WS2. In an example embodiment, the signal via portion 144VS may refer to the via portion 144V disposed between the interconnection pattern 144W disposed on the upper surface of the lowermost core insulating layer 142_L and the signal pad 144WS2.

In example embodiments, the interconnection pattern 144W and the via portion 144V may include at least one of copper (Cu), nickel (Ni), chromium (Cr), titanium (Ti), gold (Au), platinum (Pt), silver (Ag), or tungsten (W).

A ground structure may include structures directly electrically connected to the ground voltage. The ground core via 110HG, a plurality of via portions 144V and interconnection portions 144W connected to the ground core via 110HG, the lower ground pad 144WG1, and the middle ground pad 144WG2 may be directly electrically connected to the ground voltage. Accordingly, the ground core via 110HG, the lower ground pad 144WG1, and the middle ground pad 144WG2 may be referred to as parts of a corresponding one of ground structures (or ground connection paths).

A signal structure may include structures directly electrically connected to a signal voltage. The signal core via 110HS, a plurality of via portions 144V and the interconnection portions 144W connected to the signal core via 110HS, the external connection pad 144WS1, and the signal pad 144WS2 may be directly electrically connected to the signal voltage.

The signal core via 110HS, the external connection pad 144WS1, and the signal pad 144WS2 may be referred to as parts of a corresponding one of signal structures (or signal connection paths). Accordingly, the external connection pad 144WS1 and the signal pad 144WS2 may be referred to as signal structures. The signal structure may extend through a lower surface of the core stack structure 140 in a direction penetrating through the core substrate 110 and the plurality of core insulating layers 142. The signal core via 110HS included in the signal structure and the plurality of via portions 144V connected to the signal core via 110HS may extend in a direction penetrating through the core substrate 110 and the plurality of core insulating layers 142 and may be disposed to be parallel to the ground structure. A pair of the ground connection path and the signal connection path may extend in the Z-direction such that the ground structure and the signal structure are placed next to each other, and/or are arranged adjacent to each other. For example, an adjacent pair of the ground connection path and the signal connection path may extend along the same direction from an upper surface of the second core stacked structure 140 toward a lower surface of the second core stacked structure 140.

In an example embodiment, the signal pad 144WS2 may include a first end positioned outside an external side surface of the signal core via in the horizontal direction. For example, in a plan view, the first end of the signal pad 144WS2 may not overlap the signal core via 110HS. The external connection pad 144WS1 may include a second end facing away from the first end. In an example embodiment, the interconnection pattern 144WS2 may include a first end positioned outside an external side surface of the signal core via in the horizontal direction. For example, in a plan view, the first end of the interconnection pattern 144WS2 may not overlap the signal core via 110HS. The first end of the signal pad 144WS2 may be spaced apart from the signal core via 110HS in the horizontal direction. The interconnection pattern 144WS1 may include a second end facing away from the first end. In this case, the external connection pad 144WS1 may completely overlap a region in which the middle ground pad 144WG2 is disposed in a direction perpendicular to the core substrate 110 (e.g., in the Z-direction). Accordingly, the external connection pad 144WS1 may not overlap the signal core via 110HS in a plan view. When the external connection pad 144WS1 and the signal core via 110HS do not overlap each other, there is no empty space in a portion adjacent to the signal structure during the process, so that reliability during the package process may not be reduced. Therefore, the package substrate 100 may be applied to a signal structure of the package substrate used in the semiconductor package requiring a large area. For example, the reliability for physical shocks of the package substrate may be improved because an empty space in the portion adjacent to the signal structure is reduced. Additionally, since the external connection pad 144WS1 does not overlap the signal core via 110HS in a direction perpendicular to the second surface 110F2 of the core substrate (e.g., the Z-direction), a denser electric circuit structure may be designed.

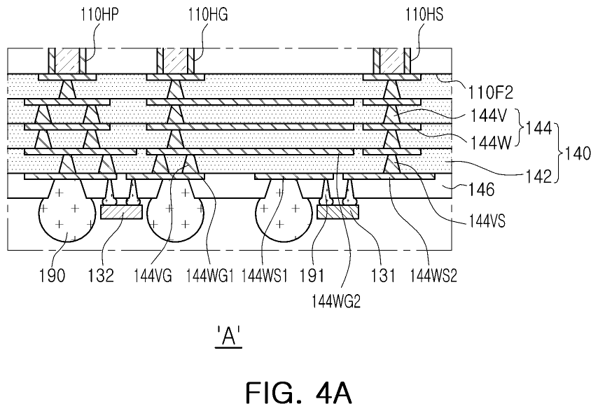

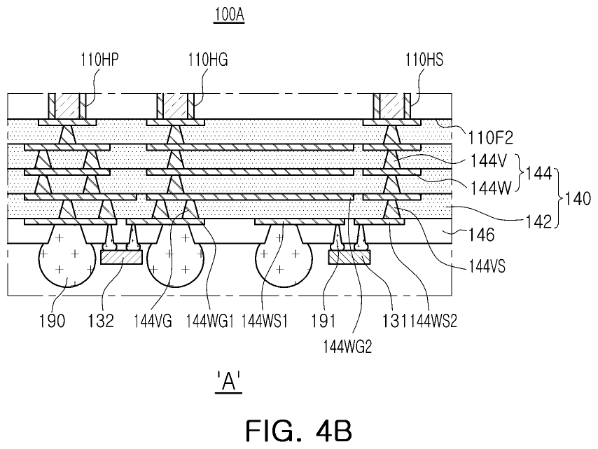

FIG. 4A is an enlarged view of part ‘A’ of FIG. 3.

Referring to FIG. 4A, the package substrate 100 may further include a solder resist layer 146, a connection bump 190, a connection portion (or conductive connector) 191, a passive component (or a second passive device) 132, and an inductor (or a first passive device) 131.

The solder resist layer 146 may be disposed on a bottom surface of the second core stack structure 140. The solder resist layer 146 may cover a portion below the lowermost core insulating layer, and may be disposed on a lower surface of the second core stack structure 140. The solder resist layer 146 may include an opening, and the opening of the solder resist layer 146 may expose the lowermost ones of the interconnection patterns 144W without covering the lowermost ones of the interconnection patterns 144W. A plurality of openings may be provided. The openings may include a first opening and a second opening that penetrate through the solder resist layer 146, thereby exposing the external connection pads 144WS1. Additionally, the openings may further include a third opening penetrating the solder resist layer 146 and exposing the signal pad 144WS2. In an example embodiment, a width of the first opening in the horizontal direction (e.g., the X-direction or Y-direction), in (or on) which the connection bump 190 is disposed, may be greater than a width of the second opening in the horizontal direction (e.g., the X-direction or Y-direction), in (or on) which a connection connector 191 is disposed, and a width of the third opening in the horizontal direction (e.g., the X-direction or Y-direction). Another conductive connector 191 may be disposed on the third opening.

In some example embodiments, the solder resist layer 146 may further expose the lower ground pad 144WG1, the external connection pad 144WS1, and the signal pad 144WS2. Each of the first opening, the second opening, and the third opening may have a shape with a width that gradually decreases in a direction oriented from the solder resist layer 146 toward the core substrate 110.

The connection bump 190 may be a solder ball formed on the lowermost ones of interconnection patterns 144W exposed by the opening of the solder resist layer 146. The connection bump 190 may be disposed in the first opening and electrically connected to the external connection pad 144WS1. The connection bump 190 may include, for example, tin (Sn), indium (In), bismuth (Bi), antimony (Sb), copper (Cu), silver (Ag), zinc (Zn), lead (Pb), and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, and Sn—Bi—Zn.

The connection portion 191 may be spaced apart from the connection bump 190 by the solder resist layer 146 on the lower ground pad 144WG1, the external connection pad 144WS1, and the signal pad 144WS2, exposed by the opening of the solder resist layer 146. For example, by the solder resist layer 146, the conductive connectors 191 may be spaced apart from the connection bumps 190, each of which are formed on a corresponding one of pads (e.g., the lower ground pad 144WG1, the external connection pad 144WS1, and the signal pad 144WS2) exposed by the solder resist layer 146.

In an example embodiment, the solder resist layer 146 and the connection portion 191 may entirely cover the lower surface of the external connection pad 144WS1. Accordingly, the connection bump 190 may not be disposed on the lower surface of the signal pad 144WS2. The connection portion (conductive connectors) 191 may be disposed in the second opening and the third opening and may electrically connect the inductor 131 to the external connection pad 144WS1 and the signal pad 144WS2. The inductor 131 may include a pair of terminals, and the connection portions 191 may electrically connect the pair of terminals to the external connection pad and the signal pad, respectively. The connection portion 191 may be an electrically conductive connector including, for example, tin (Sn), indium (In), bismuth (Bi), antimony (Sb), copper (Cu), silver (Ag), zinc (Zn), lead (Pb), and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, and Sn—Bi—Zn.

The passive component 132 may be spaced apart from the connection bump 190 on the solder resist layer 146 and may be disposed to be parallel to the connection bump 190. The passive component 132 and the connection bump 190 may be placed next to (e.g., be arranged adjacent to) each other.

The passive component 132 may be spaced apart from the inductor 131 and may be disposed on a lower surface of the solder resist layer 146. The passive component 132 may electrically connect a lower power pad (a pad directly electrically connected to the power voltage) and the lower ground pad 144WG1. The passive component 132 may include, for example, a capacitor, an inductor, and beads. The passive component 132 may improve Power Integrity (PI) characteristic of the package substrate, unlike the inductor 131 mounted between the signal structures for improving the Signal Integrity (SI) characteristic. In an example embodiment, the passive component 132 may be mounted in a lower portion of the solder resist layer 146 so as to be connected in parallel to the core interconnection layer 144 (which is connected to the power voltage) and the core interconnection layer 144 (which is connected to the ground voltage), thereby further improving the Power Integrity (PI) characteristic. For example, the passive component 132 may be disposed between one of the interconnection patterns 144W (which is connected to the power voltage) and another of the interconnection patterns 144W (which is directly electrically connected to the ground voltage). The passive component 132 may be electrically connected to the interconnection pattern 144W and the other interconnection pattern 144W, such that the passive component 132 provides an electrical parallel connection between the ground voltage and the power voltage, thereby improving the PI characteristic.

For example, a connection bump 190 may be in contact with an interconnection pattern 144W, which is directly electrically connected to a third conductive connector 191 and to the power voltage. The interconnection patterns 144W may be in contact with the third conductive connector 191, which is directly electrically connected to the passive device 132. A fourth conductive connector 191 may be in contact with the passive device 132, which is directly electrically connected to another conductive connector 191. The passive device 132 may be in contact with the fourth conductive connector, which is directly electrically connected to the interconnection pattern 144WG1. The interconnection pattern 144WG1 may be directly electrically connected to the ground voltage.

The inductor 131 may be spaced apart from the connection bump 190 on the solder resist layer 146 and may be disposed to be parallel to the connection bump 190. The inductor 131 and the connection bump 190 may be placed next to (e.g., arranged adjacent to) each other.

In an example embodiment, the inductor 131 may be coupled to the external connection pad 144WS1 and the signal pad 144WS2 through the connection portions 191. Specifically, the inductor 131 may be electrically connected to the external connection pad 144WS1 and the signal pad 144WS2 through the connection portion 191 such that the inductor 131 may be spaced apart from the connection bump 190 on the solder resist layer 146. The inductor 131 may be mounted between the external connection pad 144WS1 and the signal pad 144WS2 to transmit an electrical signal between the external connection pad 144WS1 and the signal pad 144WS2. Specifically, one electrode of the inductor 131 may be connected to the external connection pad 144WS1 through the connection portion 191 disposed in the second opening of the solder resist layer 146. The other electrode of the inductor 131 may be coupled to the signal pad 144WS2 through the connection portion 191 disposed in the third opening of the solder resist layer 146. A signal entering the external connection pad 144WS1 may be electrically transmitted to the external connection pad 144WS1, the connection portion 191, the inductor 131, the connection portion 191, and the signal pad 144WS2 in order. A signal exiting the external connection pad 144WS1 may be electrically transmitted to the signal pad 144WS2, the connection portion 191, the inductor 131, the connection portion 191, and the external connection pad 144WS1 in order. For example, a signal entering or exiting the external connection pad 144WS1 may be transmitted sequentially to or from the external connection pad 144WS1, the connection portion 191, the inductor 131, the connection portion 191 and the signal pad 144WS2, with the direction of transmission being opposite depending on whether the signal is entering or exiting the external connection pad 144WS1.

For example, a connection bump 190 may be in contact with the interconnection pattern 144WS1, which is directly electrically connected to a conductive connector (first conductive connector) 191. The interconnection pattern 144WS1 may be in contact with the conductive connector 191, which is directly electrically connected to the inductor 131. The conductive connector 191 may be in contact with the inductor 131, which is directly electrically connected to another conductive connector (second conductive connector) 191. The inductor 131 may be in contact with the second conductive connector, which is directly electrically connected to the interconnection pattern 144WS1. The interconnection pattern 144WS1 may be directly electrically connected to the signal voltage.

The electrical connection path of the interconnection pattern 144WS1, the first connection portion 191, the inductor 131, the second connection portion 191 and the signal pad 144WS2 may be a serial connection. In the serial connection path, between the interconnection pattern 144WS1 and the signal pad 144WS2, there may be no electrical branches or connections to any other components, which are electrically connected to a voltage other than the signal voltage. In addition, in a case where there is another signal voltage which is different from the signal voltage electrically connected to the interconnection pattern 144WS1 and the signal pad 144WS2, the serial connection path may have no electrical branches or connections to the other signal voltage, between the interconnection pattern 144WS1 and the signal pad 144WS2.

The electrical connection path of the interconnection patterns 144W electrically connected to the power voltage, the third connection portion 191, the passive device 132, the fourth connection portion 191 and the interconnection pattern 144WG1 may be a serial connection. In the serial connection path, between the interconnection patterns 144W electrically connected to the power voltage and the interconnection pattern 144WG1, there may be no electrical branches or connections to any other components, which are electrically connected to a voltage other than the power and ground voltages. In addition, in a case where there is another power (or ground) voltage which is different from the power (or ground) electrically connected to the interconnection patterns 144W (or the interconnection pattern 144WG1), the serial connection path may have no electrical branches or connections to the other power (or ground) voltage.

The inductor 131 may be mounted on the lower surface of the core stack structure 140. For example, the inductor 131 may include or be a surface mount device. The connector 191 disposed in the second opening of the solder resist layer 146 may extend from the external connection pad 144WS1 in the direction away from (or to an outer side of) the solder resist layer 146. The connector 191 disposed in the third opening of the solder resist layer 146 may extend from the signal pad 144WS2 in the direction away from (or to the outer side of) the solder resist layer 146. The inductor 131 mounted using a surface mount technology may be electrically connected to the external connection pad 144WS1 and the signal pad 144WS2 through the connection portion 191 disposed in the second opening and the third opening. The surface mount technology is a technology for mounting the inductor 131 on a surface of the package substrate, and may improve the reliability of the package substrate.

The inductor 131 may be electrically connected between the external connection pad 144WS1 and the signal pad 144WS2, thus offsetting the parasitic capacitance occurring between the plurality of core interconnection layers 144. In an example embodiment, the inductor 131 may offset a reactance of the parasitic capacitance between the external connection pad 144WS1 and the middle ground pad 144WG2. Accordingly, the Signal Integrity (SI) characteristics may be further improved.

FIG. 4B is a partially enlarged view illustrating a package substrate of a modified example embodiment.

Referring to FIG. 4B, a package substrate 100A according to an example embodiment may be understood as having a similar structure to the package substrate 100 illustrated in FIGS. 1 to 3, except that an area of the signal pad 144WS2 is smaller than an area of the external connection pad 144WS1. Accordingly, the description of the package substrate 100 illustrated in FIGS. 1 to 3 may be applicable to (or combined with the description of) the package substrate 100A according to this example embodiment unless otherwise described.

Specifically, in an example embodiment, the area of the signal pad 144WS2 may be smaller than the area of the external connection pad 144WS1, and an area in which the external connection pad 144WS1 overlaps the middle ground pad 144WG2 may be greater than the area in which the signal pad 144WS2 overlaps the middle ground pad 144WG2. For example, in a plan view, the area in the horizontal plane where the signal pad WS1 overlaps the middle ground pad WG2 may be greater than the area in the horizontal plane where the middle ground pad WS2 overlaps the middle ground pad WG2. Additionally, the signal pad 144WS2 may include a first end positioned outside an external side surface of the signal core via 110HS in the horizontal direction (e.g., the X-direction or the Y-direction). The external connection pad 144WS1 may include a second end facing the first end. The inductor 131 may be connected to the first end and the second end. In this example embodiment, the signal pad 144WS2 may include a third end positioned inside the external side surface of the signal core via 110HS in the horizontal direction (e.g., the X-direction or the Y-direction) and disposed to be opposite to the first end. Furthermore, there may be no area in which the signal pad 144WS2 and the middle ground pad 144WG2 overlap each other. For example, the signal pad 144WS2 may not overlap the middle ground pad 144WG2 in a plan view.

For example, the interconnection pattern 144WS2 may include a first end, and the interconnection pattern 144WS1 may include a second end. In a plan view, the first end of the interconnection pattern 144WS2 may not overlap the signal core via 110HS. The inductor 131 may be connected to the first end and the second end. The interconnection pattern 144WS2 may include a third end facing away from the first end. For example, the signal via portion 144VS may be positioned on the third end, and the third end may overlap the signal core via 110HS in a plan view.

As an area of the signal pad 144WS2 is smaller than an area of the external connection pad 144WS1, an area in which the signal pad 144WS2 and the middle ground pad 144WG2 overlap each other may be reduced, and a magnitude of the parasitic capacitance occurring between the signal pad 144WS2 and the middle ground pad 144WG2 may be reduced. Accordingly, the signal integrity may be improved. For example, in a plan view, the area in a horizontal plane occupied by the signal pad 144WS2 may be smaller than the area in the horizontal plane occupied by the external connection pad 144WS1.

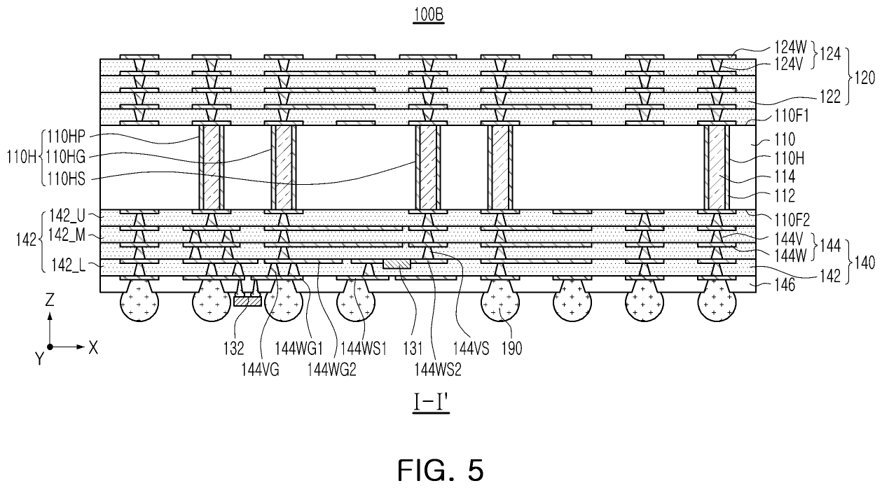

FIG. 5 is a cross-sectional view taken along line I-I′ of a package substrate according to an example embodiment.

Referring to FIG. 5, a package substrate 100B according to an example embodiment may be understood as having a structure similar to that of the package substrate 100 illustrated in FIGS. 1 to 3, except for the position of the inductor 131. For example, the inductor 131 is disposed to be parallel to the via portion 144V. Accordingly, the description of the package substrate 100 illustrated in FIGS. 1 to 3 may be applicable to (or combined with the description of) the package substrate 100B according to this example embodiment unless specifically otherwise described.

In an example embodiment, the inductor 131 may be disposed to be parallel to the via portion 144V. For example, similar to the via portion 144V, the inductor 131 may be placed between two adjacent core insulating layers 142. The inductor 131 may be disposed between a plurality of core insulating layers 142 and may form a lower conductive path electrically connected to the core substrate 110 through a plurality of second core interconnection layers (or a plurality of second core interconnection patterns) 144. The inductor 131 may be disposed, for example, between the interconnection portions 144W formed on an upper portion of the lowermost core insulating layer 142_L. The inductor 131 may be electrically connected to a plurality of via portions 144V of a signal structure through the interconnection portion 144W.

For example, a connection bump 190 may be in contact with the interconnection pattern 144WS1, which is directly electrically connected to a via 144V. The interconnection pattern 144WS1 may be in contact with the via 144V, which is directly electrically connected to an interconnection pattern 144W. The via 144V may be in contact with the interconnection pattern 144W, which is directly electrically connected to the inductor 131. The inductor 131 may be directly electrically connected to the signal voltage.

The electrical connection path of the interconnection pattern 144WS1, the via 144V, the inductor 131 and the signal pad 144WS2 may be a serial connection. In the serial connection path, between the interconnection pattern 144WS1 and the signal pad 144WS2, there may be no electrical branches or connections to any other components, which are electrically connected to a voltage other than the signal voltage. In addition, in a case where there is another signal voltage which is different from the signal voltage electrically connected to the interconnection pattern 144WS1 and the signal pad 144WS2, the serial connection path may have no electrical branches or connections to the other signal voltage, between the interconnection pattern 144WS1 and the signal pad 144WS2.

In an example embodiment, the signal pad 144WS2 may be disposed on the upper surface of the lowermost core insulating layer 142_L, among the plurality of core insulating layers 142, and the external connection pad 144WS1 may be disposed on the lower surface of the lowermost core insulating layer 142_L. The interconnection portion 144W may be disposed below the signal pad 144WS2, allowing for a more compact formation of the signal structure. Accordingly, a denser electric circuit structure may be designed. For example, an adjacent portion of the signal structure may become denser, thereby improving the reliability of the package substrate against physical shocks.

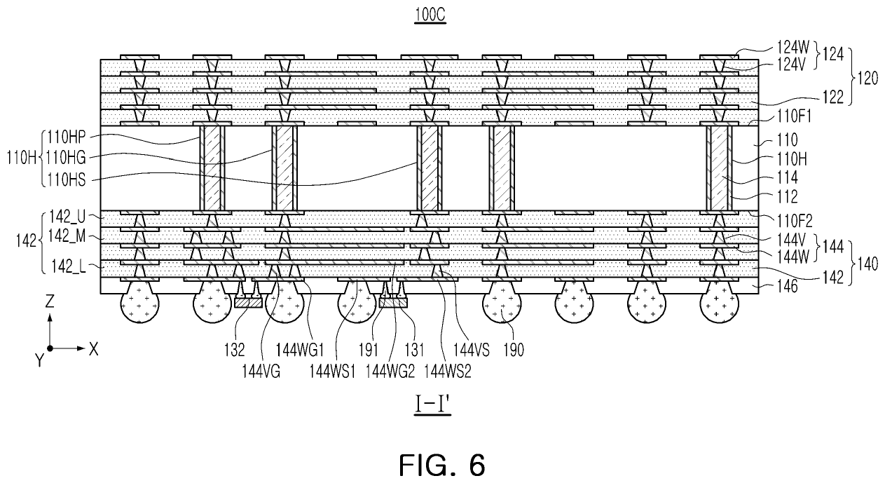

FIG. 6 is a cross-sectional view taken along line I-I′ of a package substrate according to an example embodiment.

Referring to FIG. 6, a package substrate 100C according to an example embodiment may be understood as having a structure similar to that of the package substrate 100 illustrated in FIGS. 1 to 3, except that among a plurality of via portions 144V (including 144VS) connected to the signal core via 110HS, via portions 144V (including 144VS) adjacent to each other in a vertical direction (e.g., the Z-direction) partially overlap each other in a direction (e.g., the Z-direction), perpendicular to a lower surface of the core substrate 110. Accordingly, the description of the package substrate 100 illustrated in FIGS. 1 to 3 may be applicable to (or combined with the description of) the package substrate 100C according to this example embodiment unless specifically otherwise described.

In an embodiment, a first series of via portions 144V (including 144VS) may be electrically connected to the signal core via 110HS, and each pair of adjacent via portions 144V may be spaced apart by a corresponding one of the interconnection patterns 144W. The interconnection patterns 144W disposed between each pair of adjacent via portions 144V may not be in contact with (and may not be electrically connected to) any components other than the first series of via portions 144V. Each pair of via portions 144V adjacent to each other in the vertical direction (e.g., the Z-direction) may partially overlap each other in a direction (e.g., the Z-direction), perpendicular to the lower surface of the core substrate 110. For example, among the straight lines extending in a direction (e.g., in the Z-direction), perpendicular to a lower surface (second surface) 110F2 of the core substrate 110, a straight line passing through a center of a via portion penetrating through the uppermost core insulating layer 142_U may be parallel to a straight line passing through a center of a via portion penetrating through the middle core insulating layer 142_M. In some embodiments, the first series of via portions 144V (including 144VS) electrically connected to the signal core via 110HS may include a plurality of pairs of via portions 144V. Two via portions 144V in each pair may partially overlap each other in a plan view (as viewed from the Z-direction). For example, the two via portions 144V in each pair may be positioned in two adjacent core insulating layers 142 such that a vertical straight line passing through the center of one of the two via portions 144V may be parallel to (but may not coincide with) a vertical straight line passing through the center of the other of the two via portions 144V. In some embodiments, in the first series of via portions 144V, a straight line passing through the center of the via portion (or portions) penetrating through one or all of the middle core insulating layer 142_M may be parallel to (but may not coincide with) a straight line passing through the center of a via portion penetrating through the lowermost core insulating layer 142_L. In some embodiments, in the first series of via portions 144V, the two adjacent via portions 144V (which are disposed in two adjacent core insulating layers 142) do not overlap each other in a plan view, so that the stress applied to the package substrate may be relieved. The reliability of the package substrate against physical shocks may be improved.

Though not shown in the drawings, similarly to the first series of via portions 144V described previously, a second series of via portions 144V may be electrically connected to the power core via 110HP in the same manner as (or similar manner to) the first series of via portions 144V. Accordingly, the description of the first series of via portions 144V may be applicable to the second series of via portions 144V may be electrically connected to the power core via 110HP. For example, the second series of via portions 144V electrically connected to the power core via 110HP may include a plurality of pairs of via portions 144V. Two via portions 144V in each pair may partially overlap each other in a plan view. In the case of not only a plurality of via portions 144V and 144VS connected to the signal core via 110HS, but also a plurality of via portions 144V connected to the power core via 110HP, the via portions 144V adjacent to each other in the vertical direction (e.g., the Z-direction) may partially overlap each other in a direction (e.g., the Z-direction), perpendicular to the core substrate 110.

Though not shown in the drawings, similarly to the first series of via portions 144V described previously, a third series of via portions 144V may be electrically connected to the ground core via 110HG in the same manner as (or similar manner to) the first series of via portions 144V. Accordingly, the description of the first series of via portions 144V may be applicable to the third series of via portions 144V may be electrically connected to the power core via 110HP. In the case of not only a plurality of via portions 144V and 144VS connected to the signal core via 110HS, but also a plurality of via portions 144V and 144VG connected to the ground core via 110HG, the via portions 144V and 144VG adjacent to each other in the vertical direction (e.g., the Z-direction) may partially overlap each other in a direction (e.g., the Z-direction), perpendicular to the core substrate 110.

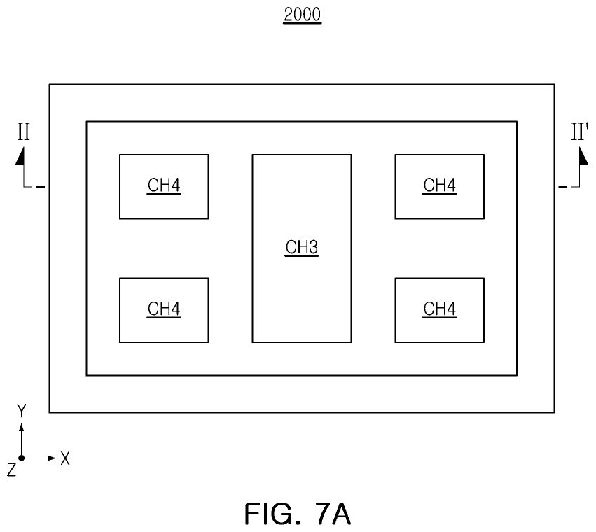

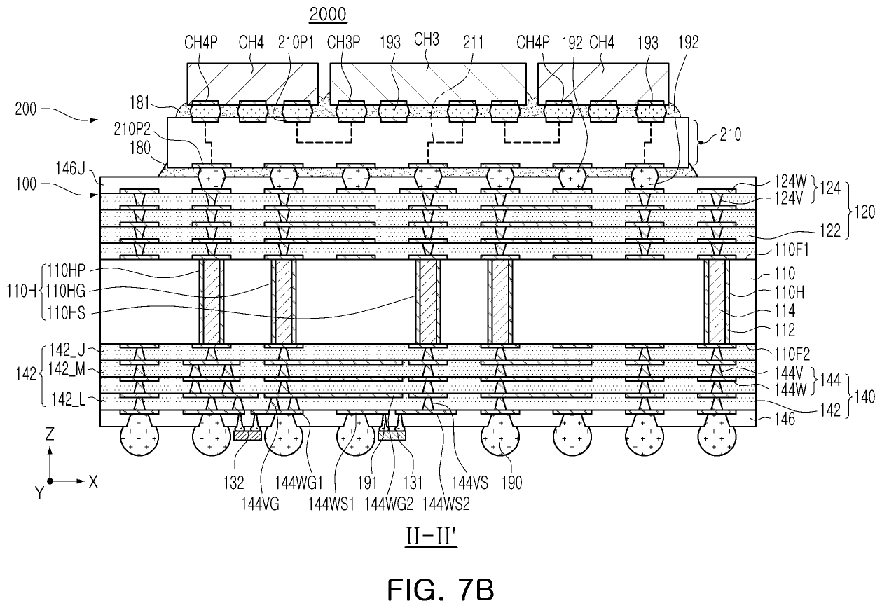

FIG. 7A is a plan view illustrating a semiconductor package according to an example embodiment, and FIG. 7B is a cross-sectional view taken along line II-II′ of FIG. 7.

Referring to FIGS. 7A and 7B, a semiconductor package 2000 may include a lower structure 100, an upper structure 200, an underfill layer 180 between the lower and upper structures 100 and 200, and a connection bump 190 disposed on a lower portion of the lower structure 100.

The lower structure 100 may be understood to have the same structure as the package substrate 100 illustrated in FIGS. 1 to 3. Accordingly, the description of the package substrate 100 illustrated in FIGS. 1 to 3 may be applicable to (or combined with the description of) the semiconductor package 2000 according to this example embodiment, unless otherwise specifically described. Alternatively, the lower structure 100 may be one of the package substrates 100A, 100B and 100C.

The upper structure 200 may include at least one semiconductor chip CH3 and CH4, an interposer substrate 210, an underfill resin 181, and a connection bump 192.

At least one semiconductor chip CH3 and CH4 may include at least one first semiconductor chip CH3 and at least one second semiconductor chip CH4. The upper structure 200 may be referred to as a unit semiconductor package 200 (or a ‘unit package structure’).

The interposer substrate 210 may include an insulating resin.

The interposer substrate 210 may be a semiconductor package substrate such as a printed circuit board (PCB), a ceramic substrate, a tape interconnection substrate, or the like. The interposer substrate 210 may include upper terminals 210P1, lower terminals 210P2, and a redistribution circuit 211 electrically connecting the upper terminals 210P1 and the lower terminals 210P2. For example, when the interposer substrate 210 is a silicon substrate, the redistribution circuit 211 may have electrical interconnection paths including through-silicon vias (TSVs), though not shown in the drawings. The semiconductor chips CH3 and CH4 may include connection pads CH3P and CH4P, respectively. The upper terminals 210P1 corresponding to connection pads CH3P and CH4P of the semiconductor chips CH3 and CH4 may be smaller in size than the lower terminals 210P2. The semiconductor chips CH3 and CH4 may be connected to the upper terminals 210P1 through a first bump 193. The interposer substrate 210 may be electrically connected to the package substrate 100 through the second bump 192.

The semiconductor chips CH3 and CH4 may be disposed on a first surface of the interposer substrate 210 and may be electrically connected to the redistribution circuit 211. The redistribution circuit 211 may include a redistribution pattern and a redistribution via. For example, the semiconductor chips CH3 and CH4 may be electrically connected to the redistribution pattern through the redistribution via. The semiconductor chips CH3 and CH4 may include at least one of the first and second semiconductor chips CH3 and CH4. For example, the first and second semiconductor chips CH3 and CH4 may be electrically connected to each other through the redistribution via and the redistribution pattern. The semiconductor chip CH3 and CH4 may be a logic chip or a memory chip. The logic chip may include, for example, a central processing unit (CPU), a graphics processing unit (GPU), a field programmable gate array (FPGA), a digital signal processor (DSP), an encryption processor, a microprocessor, a microcontroller, an analog-to-digital converter, and an application-specific integrated circuit (ASIC). The memory chip may include, for example, a volatile memory device such as a dynamic RAM (DRAM), a static RAM (SRAM), or the like, or a nonvolatile memory device such as a phase change RAM (PRAM), a magnetic RAM (MRAM), a resistive RAM (RRAM), a flash memory, or the like, or a high-performance memory device such as a high bandwidth memory (HBM), a hybrid memory cubic (HMC), or the like. At least one of the first semiconductor chips CH3 may include a memory chip, and the second semiconductor chip CH4 may include a logic chip.

In an example, the first and second semiconductor chips CH3 and CH4 may be mounted on the interposer substrate 210 in a flip-chip bonding manner. For example, the first and second semiconductor chips CH3 and CH4 may be disposed so that an active surface (on which a connection pad (e.g., the connection pads CH3P and CH4P) is disposed) faces the first surface, and may be connected to the redistribution via through the first bump 193.

The first bump 193 may include, for example, tin (Sn), indium (In), bismuth (Bi), antimony (Sb), copper (Cu), silver (Ag), zinc (Zn), lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, and Sn—Bi—Zn. The connection pad may include, for example, a metallic material such as aluminum (Al).

The underfill resin 181 may be formed to fill lower portions of the first and second semiconductor chips CH3 and CH4 on the first surface of the interposer substrate 210. For example, the underfill resin 181 may be formed to fill a space between the first surface and the first and second semiconductor chips CH3 and CH4 and surround the first bumps 193. The underfill resin 181 may include a polymer material such as an epoxy resin.

The underfill layer 180 may be formed between the lower and upper structures 100 and 200. The underfill layer 180 may fill an opening of an upper solder resist layer 146U (which is formed on the package substrate 100) and may cover uppermost ones of the interconnection patterns 124W and the second bump 192. The underfill layer 180 may fix the unit semiconductor package 200 onto the lower structure 100, between the unit semiconductor package 200 and the lower structure 100. The underfill layer 180 may include a polymer material such as an epoxy resin.

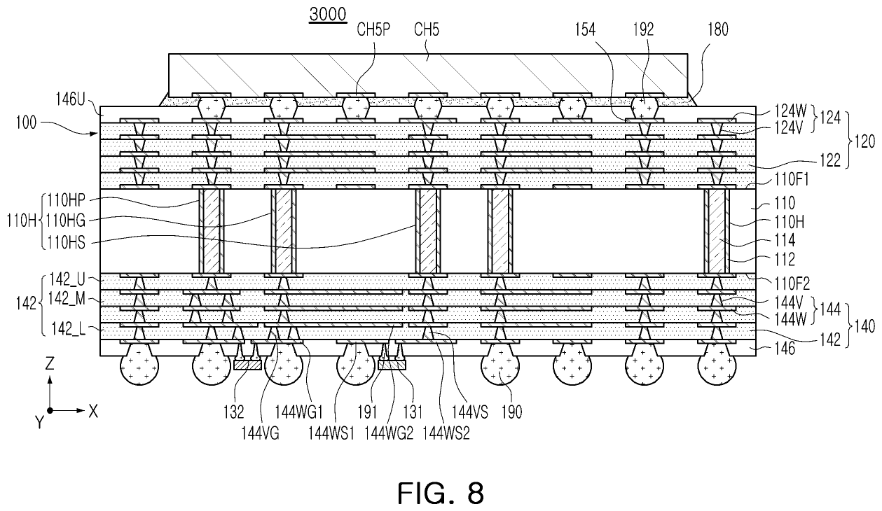

FIG. 8 is a cross-sectional view illustrating a semiconductor package according to an example embodiment.

Referring to FIG. 8, a semiconductor package 3000 may include a package substrate 100, a semiconductor chip CH5, an underfill layer 180 between the package substrate 100 and the semiconductor chip CH5, and a connection bump 190 disposed in a lower portion of the package substrate 100.

The package substrate 100 may be understood to have the same structure as the package substrate 100 illustrated in FIGS. 1 to 3. Accordingly, the description of the package substrate 100 illustrated in FIGS. 1 to 3 may be applicable to (or combined with the description of) the semiconductor package 3000 according to this example embodiment unless specifically otherwise described. Alternatively, the lower structure 100 may be one of the package substrates 100A, 100B and 100C.

The semiconductor chip CH5 may include or be a system LSI, a flash memory, a DRAM, an SRAM, an EEPROM, a PRAM, an MRAM, or an RRAM. Specifically, the semiconductor chip CH5 may include various individual devices formed in an active area. The individual devices may include, for example, a metal-oxide-semiconductor field effect transistor (MOSFET) such as a complementary metal-oxide-semiconductor transistor (CMOS transistor), and a passive device. The semiconductor chip CH5 may include an interconnection structure layer connecting a plurality of individual devices. The interconnection structure layer may include an insulating layer and a metal interconnection layer formed on the insulating layer.

In an example, the semiconductor chip CH5 may be mounted on the package substrate 100 in a flip-chip bonding manner. For example, the semiconductor chip CH5 may be disposed such that the active surface (on which the connection pad CH5P is disposed) faces the first surface. The interconnection patterns 124W may include a redistribution conductive pattern 154. The semiconductor chip CH5 may be electrically connected to the redistribution conductive pattern 154 through the second bump 192.

The second bump 192 may include, for example, tin (Sn), indium (In), bismuth (Bi), antimony (Sb), copper (Cu), silver (Ag), zinc (Zn), lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, and Sn—Bi—Zn. The connection pad may include, for example, a metallic material such as aluminum (Al).

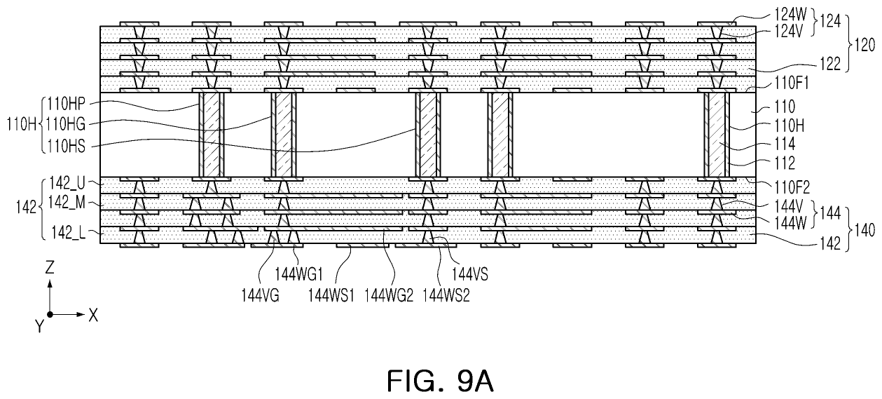

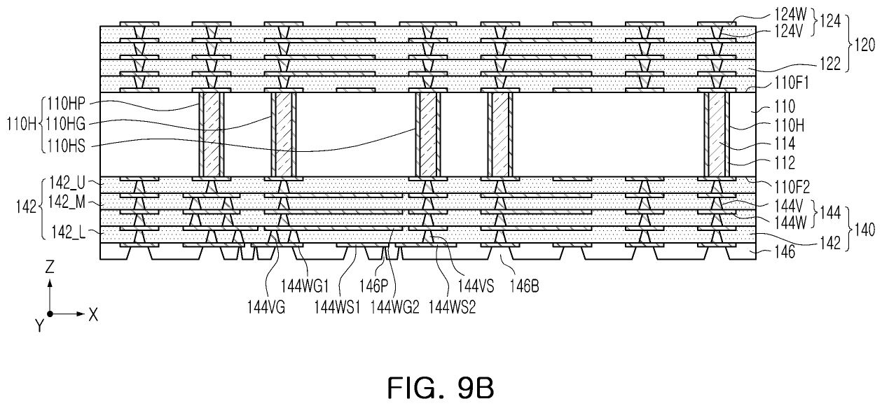

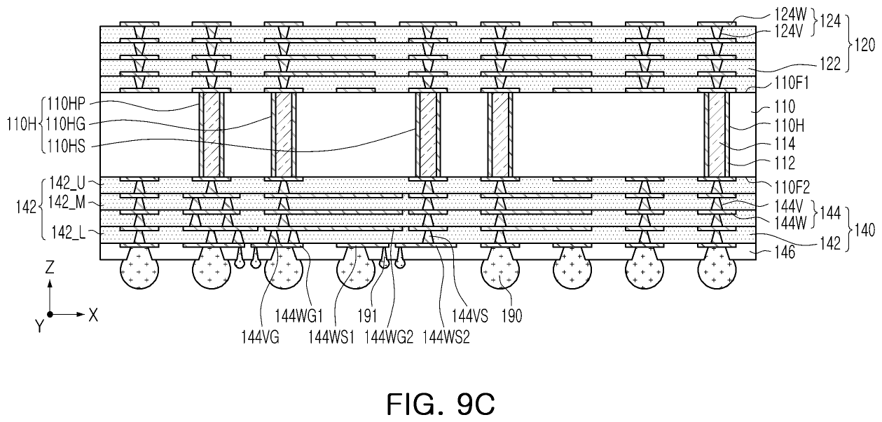

FIGS. 9A to 9C and FIG. 3 are views illustrating a manufacturing process of a package substrate according to an example embodiment. FIGS. 9A to 9C schematically illustrate a manufacturing process of a package substrate 100 according to an example embodiment illustrated in FIGS. 1 to 3. The description of the package substrates illustrated in the drawings may be applicable to the manufacturing process, unless otherwise described.

Referring to FIG. 9A, a plurality of core interconnection layers 144 may be formed in a core stack structure 140 in which a plurality of core insulating layers 142 are stacked, and on a lower surface of the core stack structure 140.

The plurality of core interconnection layers 144 may form a lower conductive path electrically connected to the core substrate 110 and may include an interconnection portion 144W and a via portion 144V. The interconnection portion 144W may be formed below the core insulating layer 142. The lowermost ones of the interconnection pattern 144W may be formed on the lower surface of the lowermost core insulating layer 142_L.

The lowermost ones of the interconnection pattern 144W may include a lower ground pad 144WG1, an external connection pad 144WS1, and a signal pad 144WS2. The lower ground pad 144WG1, the external connection pad 144WS1, and the signal pad 144WS2 may be formed to be spaced apart from each other.

Referring to FIG. 9B, a solder resist layer 146 having a plurality of openings formed thereon may be formed on the lower surface of the core stack structure 140. The solder resist layer 146 may be formed, for example, by applying a photo imageable solder resist material to the lower surface of the core stack structure 140 by a screen-printing method or a spray coating method, or by bonding a film-type solder resist material by a laminating method.

The solder resist layer 146 may cover the ground pad 144WG1, the external connection pad 144WS1, and the signal pad 144WS2 below the core stack structure 140. The solder resist layer 146 may be patterned to form a first opening exposing a first surface of the external connection pad 144WS1, a second opening exposing a second surface of the external connection pad 144WS1, and a third opening exposing the signal pad 144WS2. In this case, a width of the first opening in the horizontal direction (e.g., the X-direction or the Y-direction) may be greater than that of the second opening and the third opening.

The solder resist layer 146 may further include a fourth opening exposing a first side of a lower power pad (which is electrically connected to the power core via 110HP) and a fifth opening exposing the lower ground pad 144WG1. Additional openings 146P for disposing the connection bumps 190 may be formed.

Referring to FIG. 9C, the connection bumps 190 may be disposed and formed like solder balls on the lowermost ones of the interconnection patterns 144W exposed by the openings of the solder resist layer 146. The connection portions 191 may be disposed on the lowermost ones of the interconnection patterns 144W exposed by the additional openings 146P of the solder resist layer 146. The connection portions 191 may be formed of solder paste.

Connection portions 191 (which are disposed in the additional openings 146P) may electrically connect the inductor 131 to the external connection pad 144WS1 and the signal pad 144WS1. The connection portions 191 may further electrically connect the passive component 132 to the lower power pad and the lower ground pad 144WG1.

A size of the connection bumps 190 may be formed larger than a size of the connection portions 191.

Next, referring back to FIG. 3, the passive component 132 and the inductor 131 may be mounted on the connection portions 191 disposed on the lower surface of the solder resist layer 146. In this case, the passive component 132 and the inductor 131 may be mounted in a position, in which the plurality of connection portions 191 are disposed, using the surface mount technology.

The passive component 132 may be spaced apart from the connection bump 190 on the solder resist layer 146 and may thus be disposed in parallel with the connection bump 190. The passive component 132 and the connection bump 190 may be placed next to (e.g., arranged adjacent to) each other. The passive component 132 may be spaced apart from the inductor 131 and may be disposed on the lower surface of the solder resist layer 146. The passive component 132 may electrically connect the lower power pad (which is directly electrically connected to the power voltage) and the lower ground pad 144WG1. The inductor 131 may be spaced apart from the connection bump 190 on the solder resist layer 146 and may be disposed in parallel with the connection bump 190. The inductor 131 and connection bump 190 may be placed next to (e.g., arranged adjacent to) each other. In an example embodiment, the inductor 131 may be coupled to the external connection pad 144WS1 and the signal pad 144WS2 through the connection portion 191. The inductor 131 may be mounted on the lower surface of the solder resist layer 146 between the external connection pad 144WS1 and the signal pad 144WS2.

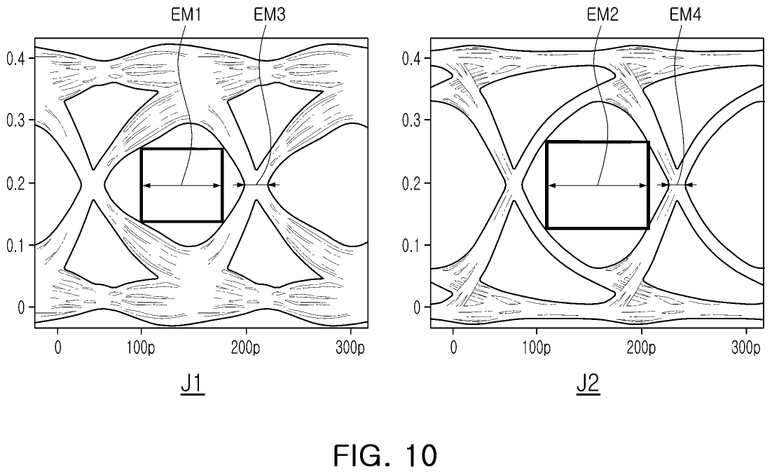

FIG. 10 is a graph illustrating signal transmission characteristics according to an example embodiment of the present disclosure.

Referring to FIG. 10, graph J1 may be a graph illustrating signal transmission characteristics transmitted from a package substrate on which an inductor 131 is not mounted. Specifically, the graph J1 may be a graph illustrating signal transmission characteristics transmitted from a package substrate on which the inductor 131 is not coupled to the external connection pad 144WS1 and the signal pad 144WS2 through the connection portion 191.

The external connection pad 144WS1 may include a region overlapping a plurality of interconnection portions 144W, so that parasitic capacitance may be formed between the external connection pad 144WS1 and the plurality of interconnection portions 144W, and between respective adjacent interconnection portions 144W. In an interconnection pattern in which the influence of parasitic capacitance is dominant, the parasitic capacitance may cause timing jitter EM3. When the timing jitter EM3 occurs, this may become a limiting factor in increasing signal transmission speed and may reduce an eye margin EM1 of a signal. This may result in deterioration of the signal integrity such as signal quality and signal transmission speed.

Graph J2 may be a graph illustrating the signal transmission characteristics transmitted from a package substrate on which the inductor 131 is mounted. Specifically, the graph J2 may be a graph illustrating the signal transmission characteristics transmitted from a package substrate on which the inductor 131 is coupled to the external connection pad 144WS1 and the signal pad 144WS2 through the connection portion 191.

The inductor 131 may be coupled to the external connection pad 144WS1 and the signal pad 144WS2 through the connection portion 191, thus offsetting the reactance of parasitic capacitance occurring between the external connection pad 144WS1 and multiple interconnection portions 144W.

In an example embodiment, the reactance of the parasitic capacitance occurring between the external connection pad 144WS1 and the middle ground pad 144WG2 may be offset to reduce timing jitter EM4 due to the inductance and the noise therefrom, and increase an eye margin EM2.

Referring to FIG. 10, the timing jitter EM4 of the graph J2 may be reduced compared to the timing jitter EM3 of the graph J1, and the eye margin EM2 of the graph J2 may be increased compared to the eye margin EM1 of the graph J1. Accordingly, the inductor 131 may improve the timing jitter, and improve the signal integrity transmitted from the package substrate.

The present invention is not limited to the above-described embodiments and the accompanying drawings. Therefore, those of ordinary skill in the art may make various replacements, modifications, or changes, and combinations of the example embodiments without departing from the scope of the present invention defined by the appended claims, and these replacements, modifications, or changes should be construed as being included in the scope of the present invention.

What is claimed is:

1. A semiconductor package, comprising:
a core substrate having a first surface and a second surface facing away from each other;
a plurality of core insulating layers stacked on the first surface of the core substrate, the plurality of core insulating layers including a lowermost core insulating layer;
a signal connection path formed through the core substrate and the plurality of core insulating layers, the signal connection path configured to be directly electrically connected to a signal voltage;
a ground connection path formed through the core substrate and the plurality of core insulating layers, the ground connection path configured to be directly electrically connected to a ground voltage;
a semiconductor chip formed on the second surface of the core substrate and electrically connected to the signal connection path and to the ground connection path; and
an inductor,
wherein the signal connection path includes:
an external connection pad disposed on a lower surface of the lowermost core insulating layer, and
a signal pad disposed on the lower surface of the lowermost core insulating layer or between the plurality of core insulating layers,
wherein the external connection pad is spaced apart from the signal pad in a horizontal direction,
wherein the ground connection path includes:
a lower ground pad disposed on the lower surface of the lowermost core insulating layer, and
a middle ground pad disposed between the plurality of core insulating layers and extending onto the external connection pad, and
wherein the inductor is mounted between the external connection pad and the signal pad and electrically connects the external connection pad and the signal pad to each other.

2. The semiconductor package of claim 1,
wherein the middle ground pad is disposed on an upper surface of the lowermost core insulating layer.

3. The semiconductor package of claim 1,
wherein an electrical connection path between the external connection pad and the signal pad is a serial connection, and
wherein, between the external connection pad and the signal pad, the serial connection is configured to have no electrical connection to a voltage other than the signal voltage.

4. The semiconductor package of claim 1,
wherein the external connection pad overlaps the middle ground pad in a direction perpendicular to the lower surface of the lowermost core insulating layer.

5. The semiconductor package of claim 4,
wherein a planar area of the external connection pad is smaller than a planar area of the middle ground pad.

6. The semiconductor package of claim 4,
wherein a planar area of the signal pad is smaller than a planar area of the external connection pad, and
an area in which the external connection pad overlaps the middle ground pad is greater than an area in which the signal pad overlaps the middle ground pad.

7. The semiconductor package of claim 1,
wherein the lower ground pad, the middle ground pad, the external connection pad, and the signal pad include copper (Cu) or alloys thereof.

8. The semiconductor package of claim 1, wherein the plurality of core insulating layers include prepreg.

9. The semiconductor package of claim 1,
wherein the ground connection path further includes a plurality of ground vias penetrating through the lowermost core insulating layer and electrically connecting the lower ground pad and the middle ground pad.

10. The semiconductor package of claim 1,
wherein the middle ground pad is one of a plurality of middle ground pads, and
the plurality of middle ground pads are disposed on a plurality of vertical levels.

11. A semiconductor package, comprising:
a substrate having a first surface and a second surface facing away from each other;
a plurality of core insulating layers stacked on the first surface of the substrate, the plurality of core insulating layers including a lowermost core insulating layer;
a semiconductor chip formed on the second surface of the substrate;
a lower ground pad disposed on a lower surface of the lowermost core insulating layer, the lower ground pad configured to be directly electrically connected to a ground voltage;
an external connection pad spaced apart from the lower ground pad and disposed on the lower surface of the lowermost core insulating layer;
a signal pad spaced apart from the lower ground pad and the external connection pad and disposed on the lower surface of the lowermost core insulating layer, the signal pad configured to be directly electrically connected to a signal voltage;
a solder resist layer disposed below the plurality of core insulating layers, wherein the solder resist layer covers the lower ground pad, the external connection pad, and the signal pad, and includes a first opening exposing a first surface of the external connection pad, a second opening exposing a second surface of the external connection pad, and a third opening exposing the signal pad;
an inductor disposed on a lower surface of the solder resist layer;
a connection bump disposed in the first opening and electrically connected to the external connection pad; and
first conductive connectors disposed in the second opening and the third opening and electrically connecting the inductor to the external connection pad and the signal pad.

12. The semiconductor package of claim 11,
wherein the inductor includes a pair of terminals, and
the first conductive connectors electrically connect the pair of terminals to the external connection pad and the signal pad, respectively.

13. The semiconductor package of claim 11, further comprising:
a passive component spaced apart from the inductor and disposed on the lower surface of the solder resist layer; and
a lower power pad disposed on the lower surface of the lowermost core insulating layer adjacent to the lower ground pad, and
wherein the passive component electrically connects the lower power pad and the lower ground pad, and
the lower power pad is configured to be directly electrically connected to a power voltage.

14. The semiconductor package of claim 13, further comprising second conductive connectors,
wherein the solder resist layer further includes:
a fourth opening exposing a first surface of the lower power pad, and
a fifth opening exposing the lower ground pad, and
wherein the second conductive connectors are disposed in the fourth opening and the fifth opening and electrically connect the passive component to the lower power pad and the lower ground pad.

15. The semiconductor package of claim 11,
wherein a width of the first opening in a horizontal direction is greater than a width of the second opening in the horizontal direction.

16. The semiconductor package of claim 11, further comprising second conductive connectors,
wherein the solder resist layer and the second conductive connectors cover a lower surface of the signal pad, and
the lower surface of the signal pad and the connection bump are spaced apart from each other.

17. The semiconductor package of claim 11,
wherein the first opening, the second opening, and the third opening have a shape with a width that gradually decreases in a direction toward the substrate.

18. A semiconductor package, comprising:
a plurality of core insulating layers having a first surface and a second surface facing away from the first surface;
a signal connection path formed through the plurality of core insulating layers and extending from the first surface to the second surface, wherein the signal connection path is configured to be directly electrically connected to a signal voltage; and
a semiconductor chip formed on the second surface of the plurality of core insulating layers and electrically connected to the signal connection path,
wherein the signal connection path includes:
a plurality of vias each of which penetrates through a corresponding one of the plurality of core insulating layers,
a first interconnection pattern contacting a lowermost one of the plurality of vias, and extending horizontally along a lower surface of the plurality of core insulating layers,
a second interconnection pattern spaced apart from the first interconnection pattern in a horizontal direction and disposed on the lower surface of the plurality of core insulating layers,
a connection bump electrically connected to and in contact with the second interconnection pattern, and
an inductor disposed between the first and second interconnection patterns,
wherein the first and second interconnection patterns are electrically connected to each other through the plurality of vias,
wherein the first interconnection pattern includes a first end and a second end opposite the first end,
wherein the second interconnection pattern includes a first end and a second end opposite the first end,
wherein the second end of the second interconnection pattern is adjacent to the first end of the first interconnection pattern, and
wherein the inductor is connected to the first end of the first interconnection pattern and the second end of the second interconnection pattern.

19. The semiconductor package of claim 18,
wherein an electrical connection path between the connection bump and the first interconnection pattern is a serial connection, and
wherein, between the connection bump and the first interconnection pattern, the serial connection has no electrical connection configured to a voltage other than the signal voltage.

20. The semiconductor package of claim 18,
wherein:
the plurality of core insulating layers includes lowermost core insulating layer,
the first interconnection pattern is disposed on an upper surface of the lowermost core insulating layer, and
the second interconnection pattern is disposed on a lower surface of the lowermost core insulating layer.
